(19) United States
(12) Patent Application Publication
(10) Pub. No.: US 2025/0265394 A1
(43) Pub. Date: Aug. 21, 2025

(54) TECHNIQUES FOR GENERATING THREE-DIMENSIONAL DESIGN OBJECTS USING MACHINE LEARNING MODELS

(71) Applicant: AUTODESK, INC., San Francisco, CA (US)

(72) Inventors: Somashekar Ramachandran SUBRAHMANYAM, Novi, MI (US); Jingyi WEN, Woburn, MA (US); Rasa LAZAREVIC, Sydney (AU); Krish SETH, Chicago, IL (US); Ajit SHELKE, Maharashtra (IN)

(21) Appl. No.: 19/056,615

(22) Filed: Feb. 18, 2025

Related U.S. Application Data
(60) Provisional application No. 63/556,176, filed on Feb. 21, 2024.

(51) Int. Cl. G06F 30/27

(52) U.S. Cl. CPC G06F 30/27

(57) ABSTRACT

In various embodiments, a computer-implemented method for generating a design object via a design exploration application comprises receiving an intent input, where the intent input includes at least a textual input, generating, based on the intent input, a design prompt, generating, via a trained machine learning (ML) model, a three-dimensional object based on the design prompt, converting the three-dimensional object to the design object, where the design object includes one or more editable features, and adding the design object to a design space.

### CROSS-REFERENCE TO RELATED APPLICATIONS

This application claims priority benefit of United States Provisional Patent Application titled, “TECHNIQUES FOR GENERATING THREE-DIMENSIONAL DESIGNS FROM TEXT PROMPTS,” filed on Feb. 21, 2024, and having Ser. No. 63/556,176. The subject matter of this related application is hereby incorporated herein by reference.

### BACKGROUND

### Field of the Various Embodiments

The various embodiments relate generally to computer-aided design and artificial intelligence, and, more specifically, to techniques for generating three-dimensional design objects using machine learning models.

### Description of the Related Art

Design exploration for three-dimensional (3D) objects generally refers to a phase of a design process during which a designer generates and evaluates various designs alternatives for one or more 3D objects within a larger 3D design project. As is well-understood in practice, manually generating multiple designs for even a relatively simple 3D object can be very labor-intensive and time-consuming. Because the time allocated for generating a design (a 3D design object) for a specific 3D object is usually limited, users typically produce only a small number of 3D design objects, which can reduce the overall quality of the final design due to the lack of options. Accordingly, various conventional computer-aided design (CAD) applications have been developed that attempt to automate the generation and evaluation of 3D design objects.

One approach to automating how CAD applications generate and evaluate 3D design objects involves implementing an artificial intelligence (AI) model, such as a generative machine learning model, to automatically synthesize content items, such as text or images in response to a prompt provided by the user. The prompt provided to the AI model is usually in the form of a design problem statement that specifies one or more design characteristics to which the generated content item should adhere. The prompt can include any number of quantitative goals, physical objects, physical and functional constraints, and/or mechanical and geometric quantities that guide how the AI model should generate a content item. The AI model responds to the prompt by executing various optimization algorithms to generate content items that satisfy the applicable design characteristics specified in the prompt. In some cases, the AI model generates content items that the user selects for use in the larger 3D design project. In other cases, the AI model generates multiple content items. A design exploration application generates multiple design alternatives based on the content items and presents those design alternatives to a user within a design space. The user subsequently explores the design space, where different design alternatives can be viewed and evaluated to select the best design alternative to incorporate into the larger 3D design project.

One drawback of the above approach is that conventional CAD applications do not incorporate the content produced by the AI models when generating an overall 3D design. Oftentimes, when a user generates a new 3D design object, a user needs to nominate distinct preserve geometries, obstacle geometries, and starting shape geometries, as well as specify objectives and manufacturing parameters. In this regard, the use of the AI models to generate usable components for an overall 3D design is limited to highly skilled users. Such users can specify technical prompts to generate applicable content items and can manually modify the content items produced by the AI models to be incorporated into the overall 3D design. Consequently, less experienced users avoid using AI models when generating designs due to the complex and time consuming nature of interacting with the AI models and incorporating generated content items into an overall 3D design. Further, the need to manually convert content items generated by the AI models into 3D design objects that are usable within the design exploration application substantially reduces overall design quality, as such manual modifications may conflict with one or more design parameters specified in the original design problem statement.

As the foregoing illustrates, what is needed in the art are more effective techniques for automatically generating designs using artificial intelligence models.

### SUMMARY

In various embodiments, a computer-implemented method for generating a design object via a design exploration application comprises receiving an intent input, where the intent input includes at least a textual input, generating, based on the intent input, a design prompt, generating, via a trained machine learning (ML) model, a three-dimensional object based on the design prompt, converting the three-dimensional object to the design object, where the design object includes one or more editable features, and adding the design object to a design space.

At least one technical advantage of the disclosed techniques relative to the prior art is that the disclosed techniques enable design systems to incorporate generative artificial intelligence systems that determine the design intent of a user more accurately. Further, design systems that use the disclosed techniques can automatically convert content items produced by such generative artificial intelligence systems to parametric-based design objects that include a set of editable features. In that regard, the disclosed techniques provide an automated process for generating prompts from inputs provided by the user, such as combinations of text, speech, sketches, images, and/or stored designs. Generating prompts using varying types of data enables the user to provide additional context to portions of a prompt that a trained generative artificial intelligence model can understand, which enables the generative artificial intelligence model to infer the design intents and ideas of the user with greater accuracy. Further, by automatically converting content items into parametric-based 3D design objects that can be easily added to the design space, the design system can quickly incorporate outputs of the generative artificial intelligence system into overall 3D designs to generate large numbers of alternative designs. Accordingly, with the disclosed techniques, 3D design objects that align better with the actual design-oriented intentions and ideas of users can be more readily generated and manufactured. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is an exemplar technique of the design exploration application of FIG. 1 producing a generated design object based on a design prompt, according to various embodiments;

FIG. 4 is an exemplar illustration of design exploration application of FIG. 2 causing the GUI to display the prompt area, according to various embodiments;

FIG. 5 is an exemplar illustration of an update to the prompt input area of FIG. 4, according to various embodiments;

FIG. 6 is an exemplar illustration of the generated 3D object of FIG. 5 being added to the design space 410, according to various embodiments.

FIG. 7 is an exemplar illustration of the 3D object of FIG. 6 converted to a design object including a set of features, according to various embodiments;

FIG. 8 is another exemplar illustration of an update to the design space of FIG. 2, according to various embodiments;

FIG. 9 is an exemplar illustration of a menu for the feature extractor of FIG. 3 within the design space, according to various embodiments;

FIG. 10 is an exemplar illustration of the feature extractor of FIG. 3 generating a plurality of design object and a list of editable features, according to various embodiments;

FIG. 11 sets forth a flow diagram of method steps for generating 3D objects, according to various embodiments; and

FIG. 12 depicts one architecture of a system within which embodiments of the present disclosure may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

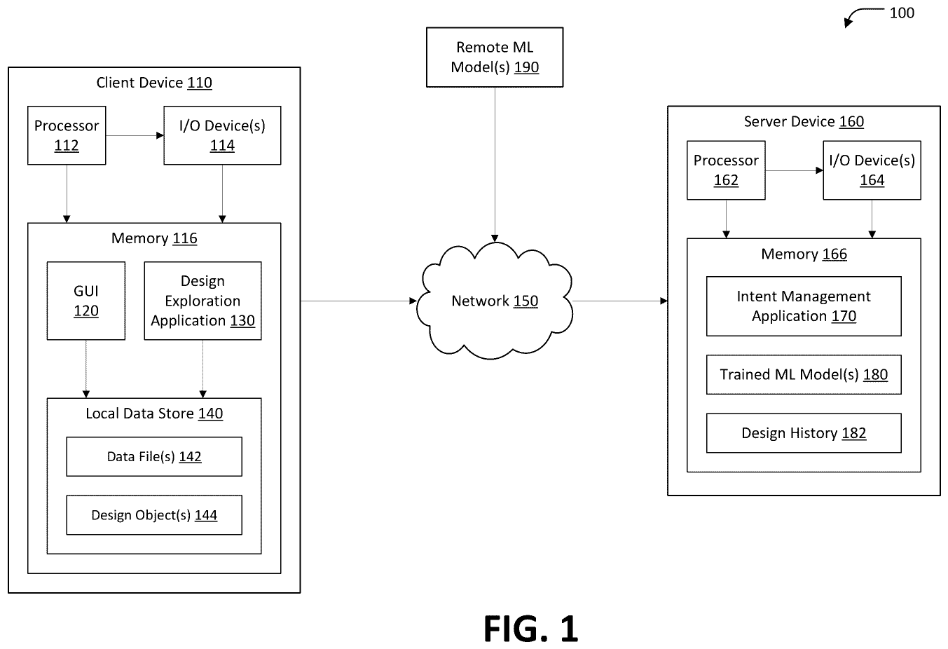

FIG. 1 is a conceptual illustration of a system 100 configured to implement one or more aspects of the various embodiments. As shown, in some embodiments, the system 100 includes, without limitation, a client device 110, a server device 160, and one or more remote machine learning (ML) models 190. The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142 and one or more design objects 144. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate 3D designs. In operation, the design exploration application 130 causes one or more ML models 180, 190 to synthesize 3D designs based on any number of goals and constraints. The design exploration application 130 then presents the designs as one or more design objects 144 to a user in the context of a design space. In some embodiments, the user can explore and modify the one or more design objects via the GUI 120. Additionally, or alternatively the user can also include at least one of the design objects 144 for use in additional design and/or manufacturing activities.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally, or alternatively the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In some embodiments, the design exploration application 130 and one or more separate applications (not shown) interact with the same user via the GUI 120. In various embodiments, the design exploration application 130 operates as a 3D design application to generate and modify an overall 3D design that includes one or more design objects 144. The design exploration application 130 interacts with a user via the GUI 120 in order to generate the one or more design objects 144 via direct user input (e.g., one or more tools to generate design objects, wireframe geometries, meshes, etc.) or using separate devices (e.g., the trained ML models 180, the remote ML models 190, separate 3D design applications, etc.). When generating the one or more design objects 144 using separate devices, the design exploration application 130 generates a prompt that effectively describes design-related intentions using one or more modalities (e.g., text, speech, images, etc.). The design exploration application 130 then causes the one or more of the ML models 180, 190 to operate on the generated prompt to generate a relevant content item. The design exploration application 130 receives the content item from the one or more ML models 180, 190 and displays the content item within the GUI 120. The user can select via the GUI 120 the for use in generating a design object 144, such as converting an image into a parametric-based design object 144 that includes a set of editable features. In such instances, the user can modify one or more features of the design object 144 and can incorporate the design object 144 into a larger 3D design.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall 3D design and/or one or more data files 142 associated with 3D design. For example, an overall 3D design for a building can include multiple stored design objects 144, including design objects 144 separately representing doors, windows, fixtures, walls, appliances, and so forth. The local data store 140 can also include data files 142 relating to a generated overall 3D design (e.g., component files, metadata, etc.). Additionally, or alternatively the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The design objects 144 include geometries (e.g., vertices, edges, and/or faces), textures, images, and/or other components that the design exploration application 130 uses to generate portions of an overall 3D design. In various embodiments, the geometry of a given design object 144 refers to any multi-dimensional model of a physical structure, including CAD models, meshes, and point clouds, as well as circuit layouts, piping diagrams, free-body diagrams, and so forth. In various embodiments, the design object 144 includes a set of features that can be separately editable and/or modified. In such instances, the design exploration application 130 can apply alternative designs based on varying parametric values for each of the respective features. For example, the design exploration application 130 can identify a plurality of parametric values for a given feature (e.g., varying type values for an identified hole). The design exploration application 130 can then generate a plurality of alternative designs for an overall 3D design by selecting one of the parametric values for the given feature.

In some embodiments, the design exploration application 130 stores multiple design objects 144 for a given 3D design and stores multiple iterations of a given target object that the ML models 180, 190. For example, the user can form an initial prompt using the design exploration application 130 and receive a first generated design object 144(1) from the trained ML model 180(1), then refine the prompt and receive a second generated design object 144(2) from the trained ML model 180(1).

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more design objects 144. In operation, the server device 160 executes the intent management application 170 to process a prompt generated by the design exploration application 130, select one or more ML models 180, 190 trained to generate content items in response to the contents of the prompt, and input the prompt into the selected ML models 180, 190. Once the selected ML models 180, 190 generate the content items that are responsive to the prompt, the server device 160 transmits the generated content items to the client device 110, where the generated content items are usable by the design exploration application 130 to generate design objects 144 for the overall 3D design.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally, or alternatively the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally, or alternatively the intent management application 170 could be executed on the client device 110 and can communicate with the trained ML models 180 operating at the server device 160.

In various embodiments, the intent management application 170 receives a prompt from the design exploration application 130 and inputs the prompt into an applicable ML model 180, 190. In some embodiments, one or more of the ML models 180, 190 are trained to respond to specific types of inputs, such as a ML model that is trained to generate content items (e.g., text, images, 3D volumes, etc.) from a specific combination of modalities (e.g., text, images, audio data, etc.). In such instances, the intent management application 170 processes a prompt to determine the modalities of the data that are included in the prompt and identifies one or more ML models 180, 190 that have been trained to respond to such a combination of modalities. Upon identifying the one or more ML models, the intent management application 170 selects an ML model (e.g., the trained ML model 180(1)) and inputs the prompt into the selected ML model 180(1).

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are trained ML models that communicate with the server device 160 to receive prompts via the intent management application 170. In some embodiments, the trained ML model 180 is trained using various combinations of data from multiple modalities, such as textual data, image data, sound data, and so forth. The trained ML model 180 and/or the remote ML model 190 trained using at least two modalities of data are also referred to herein as a multimodal ML model. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate content items from various combinations of modalities. Such combinations include text, a CAD object, a geometry, an image, a sketch, a video, an application state, an audio recording, etc.).

The design history 182 includes data and metadata associated with the one or more trained ML models 180 and/or the one or more remote ML models 190 generating design objects 144 in response to prompts provided by the design exploration application 130. In some embodiments, the design history 182 includes successive iterations of design objects 144 that a single ML model 180 generates in response to a series of prompts. Additionally, or alternatively the design history 182 includes multiple design objects 144 that were generated by different ML models 180, 190 in response to the same prompt. In some embodiments, the design history 182 includes feedback provided by the user for a given design object 144. In such instances, the server device 160 can use the design history 182 as training data to further train the one or more ML models 180. Additionally, or alternatively the design exploration application 130 can retrieve contents of the design history 182 and display the retrieved contents to the user via the GUI 120.

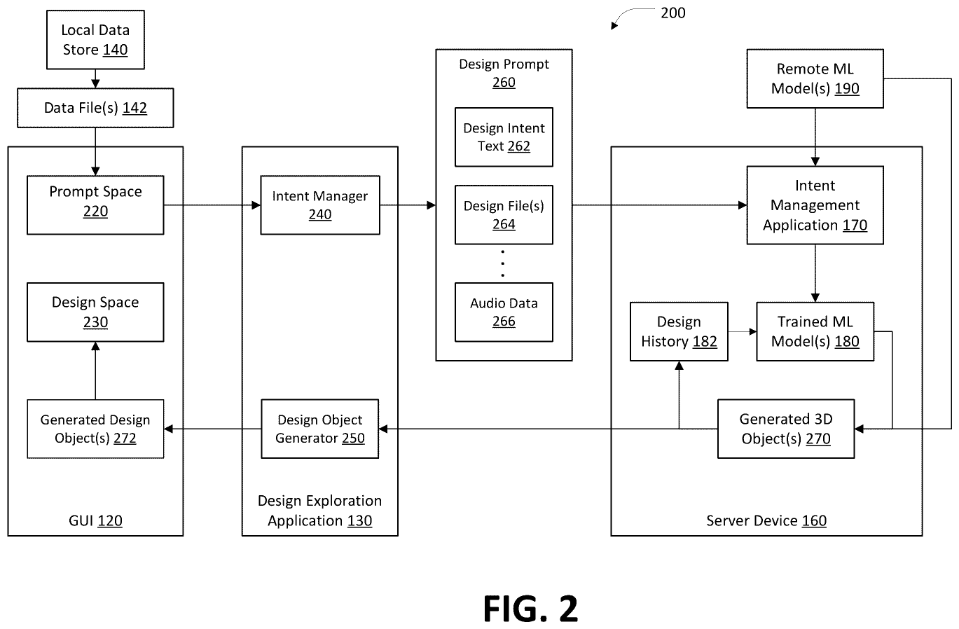

FIG. 2 is a more detailed illustration of the design exploration application 130 of FIG. 1, according to various embodiments. As shown, in some embodiments, the system 200 includes, without limitation, the GUI 120, the design exploration application 130, the local data store 140, the one or more data files 142, the server device 160, the one or more remote ML models 190, the and a design prompt 260. The GUI 120 includes, without limitation, a prompt space 220, a design space 230, and one or more generated design objects 272. The design exploration application 130 includes, without limitation, an intent manager 240 and a design object generator 250. The server device 160 includes, without limitation, the intent management application 170, the one or more trained ML models 180, the design history 182, and one or more generated 3D objects 270. The design prompt 260 includes, without limitation, design intent text 262, one or more design files 264, and audio data 266.

For explanatory purposes only, the functionality of the design exploration application 130 is described herein in the context of exemplar interactive and linear workflows used to generate the generated design object 272 in accordance with user-based design-related intentions expressed during the workflow. The generated design object 272 includes, without limitation, one or more parametric-based content items, such as images, wireframe models, geometries, and/or meshes for use a three-dimensional design, as well and any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 272 associated with any target 3D object in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target 3D objects and/or target 3D object components.

For example, in some embodiments, a generated 3D object 272 can be generated and displayed within the GUI 120 during a first iteration, any portion (including all) of the generated 3D object 270 can be selected via the GUI 120, and a first design prompt 260 can be set equal to the selected portion of the generated 3D object 272 to recursively generate a second generated 3D object 270 via the one or more ML models 180, 190 and the design object generator 250 during a second iteration. In the same or other embodiments, the design exploration application 130 can display and/or re-display any number of GUI elements (e.g., the generated 3D objects 270), generate and/or regenerate any amount of data, or any combination thereof any number of times and/in any order while producing each new generated design object 272.

In operation, the design exploration application 130 causes the GUI 120 to display the design space 230. A user triggers the GUI 120 to display the prompt space 220 and provides the contents for the design prompt 260 via the prompt space 220. The design exploration application 130 processes the content to generate the design prompt 260 and transmits the design prompt 260 to the server device 160. The intent management application 170 identifies the contents included in the design prompt 260. The intent management application 170 identifies one or more trained ML models 180 and/or remote ML models 190 that have been trained to process the combination of modalities corresponding to the identified contents. The intent management application 170 inputs the design prompt 260 into one or more of the identified ML models 180, 190. The identified ML models 180, 190 respond to the design prompt 260 by generating one or more generated 3D objects 270. The design object generator 250 receives the one or more generated 3D objects 270 and converts the generated 3D objects 270 to one or more generated design objects 272. The design exploration application 130 displays the one or more generated design objects 272 in the prompt space 220 and/or the design space 230.

In various embodiments, the design space 230 is a virtual workspace that includes one or more renderings of design objects (e.g., geometries of the design objects 144 and/or the generated design objects 272) that form an overall 3D design. In some embodiments, the design space 230 includes multiple design alternatives for the overall 3D design. For example, the design space 230 may graphically organize multiple 3D designs that include differing combinations of design objects 144, 272. In such instances, the user interacts with the GUI to navigate between design alternatives to quickly analyze tradeoffs between different design options, observe trends in design options, constrain the design space, select specific design options, and so forth.

The prompt space 220 is panel, window, and/or portion of the GUI 120 in which a user can generate prompts, such as the design prompt 260. In some embodiments, the prompt space 220 is a panel, such as a window separate from the design space. Alternatively, in some embodiments, the prompt space 220 is a window, panel, or other graphic element overlays at least a portion of the design space 230. In such instances, a user can invoke the prompt space 220 as a prompt input area at various locations within the design space 230. The user can then input data that is to be included in a design prompt 260.

In various embodiments, the intent manager 240 determines the intent of inputs provided by the user. For example, the intent manager 240 can comprise a natural language (NL) processor that parses text provided by the user. Additionally, or alternatively the intent manager 240 can include processes audio data to identify words included in audio data and parse the identified words. In various embodiments, the intent manager 240 identifies one or more keywords in textual data. In some embodiments, the intent manager 240 includes one or more keyword datasets (not shown) that the intent manager 240 references when identifying the one or more keywords included in textual data. For example, the keyword datasets can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user). The keywords can comprise particular words or phrases (e.g., demonstrative pronouns, technical terms, referential terms, etc.) that are relevant to designing 3D objects. For example, a user can input a regular sentence (“I want a fastener to connect these faces”) within the prompt space 220. The intent manager identifies “fastener,” “connect,” and “faces” as words relevant to the ML model 180, 190 when generating content items for producing the generated design object 272. In such instances, the intent manager 240 can include, supplement, and/or replace the identified keywords as part of the design intent text 262.

In various embodiments, the design exploration application 130 updates the prompt space 220 and/or the design space 230 based on inputs by the user and/or data received from the server device 160. For example, the design exploration application 130 can initially respond to the user invoking a prompt via a hotkey or a marking menu by displaying the prompt space 220 to receive data to include in the design prompt 260. When the user initially inputs one or more types of data within the prompt space 220, the design exploration application can generate and transmits the design prompt 260 to the server device 160. Upon receipt of the generated 3D object 270, the design exploration application 130 can then update the prompt space 220 to further include the generated 3D object 270.

In various embodiments, the design exploration application 130 receives textual and/or non-textual data to include in the design prompt 260 via the input areas included in the prompt space 220. When providing non-textual data, the user can retrieve stored data, such as one or more stored data files 142 (e.g., stored geometries, stored CAD files, audio recordings, stored sketches, etc.) from the local data store 140. Additionally, or alternatively the user can retrieve contents from the design history 182 and can add the contents into the input area. In such instances, the contents from the design history 182 can be stored in one or more data files 142 that the user retrieves from the local data store 140 and/or the server device 160.

The design prompt 260 is a prompt that includes one or more modalities of data (e.g., textual data, image data, audio data, etc.) that specifies the design intent of the user. In various embodiments, the design exploration application 130 receives one or more types of data and builds the design prompt 260 to include the data received. For example, a user can initially write design intent text 262 that is a natural language phrase, as well as an uploaded sketch. Upon receiving the sketch, the design exploration application 130 can then generate the design prompt 260 to include both the design intent text 262 and the sketch (e.g., the design file 264(1)). In some embodiments, the design prompt 260 can include multiple data inputs of the same modality. For example, the design prompt 260 can include multiple design intent texts 262 (e.g., 262(1), 262(2), etc.) and/or multiple design files 264 (e.g., 264(1), 264(2), etc.).

The design intent text 262 includes textual data that describes the intent of the user. For example, the design intent text can include descriptions for characteristics of a target 3D design object (e.g., “a chrome hubcap”). In some embodiments, the design exploration application 130 generates design intent text 262 from a different type of data input. For example, the prompt space 220 can include a set of sliders for specific parameter values, such as grid size and guidance scale. In such instances, the design exploration application 130 can include respective the numerical values for the respective sliders as additional design intent texts 262 (e.g., 262(2) and 262(3)) to supplement the entered phrase. In another example, the intent manager 240 can perform NL processing to identify words included in an audio recording. In such instances, the design exploration application 130 generates design intent text 262 that includes the identified words.

The design files 264 include one or more files (e.g., CAD files, stored text, audio recordings, stored geometries, etc.) that the user adds to be included in the design prompt 260. In some embodiments, the design files 264 can include textual data (e.g., textual descriptions, physical dimensions, etc.). In various embodiments, a user can add multiple design files 264 to include in the design prompt 260. In some embodiments, the design exploration application 130 converts various types of data into the design files 264. For example, the user can enter a sketch via the input area of the prompt space 220. In such instances, the design exploration application 130 can store sketch as a design file 264. The design files 264 can include one or more modalities (e.g., textual data, video data, audio data, image data, etc.). In some embodiments, some types of data can be separate. For example, the design prompt 260 can include audio data 266 (e.g., spoken descriptions directly into the input area and/or stored audio files) as separate from the design files 264.

In various embodiments, the intent management application 170 receives and processes the design prompt 260 to identify the modalities of the contents of the design prompt 260. For example, the intent management application 170 can identify the modalities of the design intent text 262, the one or more design files 264, and/or the audio data 266 included in the design prompt 260. The intent management application 170 then identifies at least one ML model 180, 190 that was trained with that combination of modalities identified in the contents of the design prompt 260 and selects one of the identified ML models 180, 190. The intent management application 170 executes the selected ML model by inputting the design prompt 260 into the selected ML model. The selected ML model produces the generated 3D object 270 in response to the design prompt 260. In some embodiments, the server device 160 includes the generated 3D object 270 in the design history 182. In such instances, the generated 3D object 270 is a portion of the design history 182 used as training data to train one or more trained ML models 180 (e.g., further training the selected ML model, training other ML models, etc.). Once the selected ML model 180, 190 produces the generated 3D object 270, the server device 160 transmits the generated 3D object 270 to the design exploration application 130.

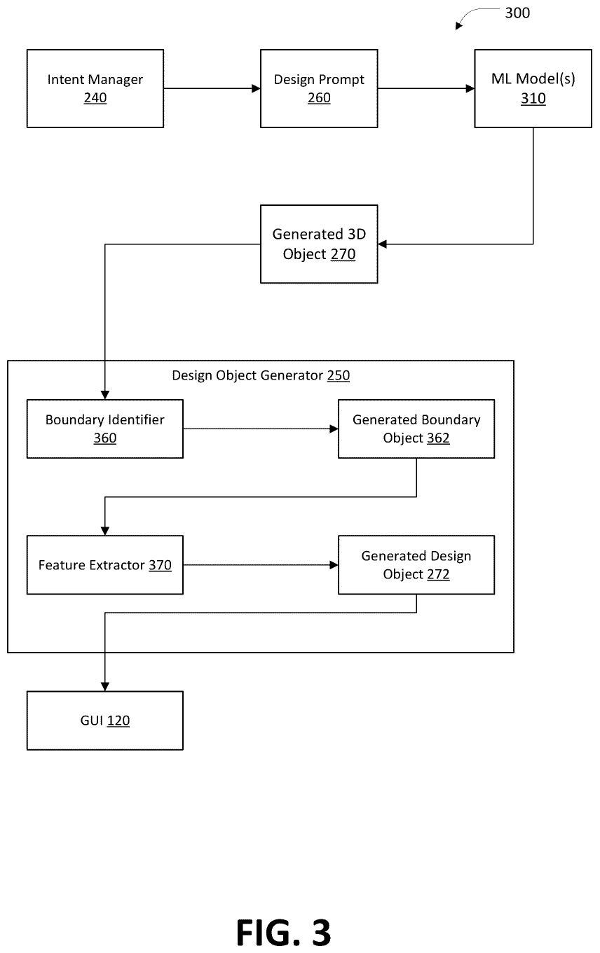

The design object generator 250 processes the generated 3D object 270. In various embodiments, the generated 3D object 270 can be a mesh or a point cloud that does not have separately editable components. For example, the generated 3D object can be a mesh of a table where the individual legs of the table are not separate and cannot be separately editable. In such instances, the design object generator 250 can automatically convert the generated 3D object 270 into the generated design object 272, where the generated design object 272 is parametric-based and has a corresponding set of features. As will be discussed further with respect to FIG. 3, in some embodiments, the design object generator 250 can produce intermediate objects and components (e.g., boundary objects, textures, etc.) when producing the generated design object 272. In some embodiments, the design exploration application 130 can cause the GUI 120 to display the generated 3D object 270. For example, the design exploration application 130 can update a preview area that is included in the prompt space 220 to display the generated 3D object 270. The user can then perform actions (e.g., drag-and-drop, select button, etc.) to select the generated 3D object 270 for use in the design space 230. In such instances, the design object generator 250 can respond to the selection of the generated 3D object 270 by producing the generated design object 272. The user can then modify one or more of the set of features that correspond to the generated design object 272.

### Generating Design Objects Using Machine Learning Models

FIG. 3 is an exemplar technique of the design exploration application 130 of FIG. 1 producing a generated design object 272 based on a design prompt 260, according to various embodiments. As shown, the configuration 300 includes, without limitation, the intent manager 240, the design prompt 260, one or more ML models 310, the generated 3D object 270, the design object generator 250, and the GUI 120. The design object generator 250 includes, without limitation, a boundary identifier 360, a generated boundary object 362, a feature extractor 370, and the generated design object 272.

In operation, the intent manager 240 included in the design exploration application 130 generates and transmits the design prompt 260. The design prompt 260 is transmitted to one or more ML models 310 (e.g., the trained ML models 180 and/or the remote ML models 190). The one or more ML models 310 generate the 3D object 270 and the generated 3D object 270 is transmitted to the design object generator 250 included in the design exploration application 130. The design object generator 250 converts the generated 3D object 272 to a design object 272, where the generated design object 272 is parametric-based and has a corresponding set of features that the user can edit via the GUI 120.

As discussed in FIG. 2, the intent manager 240 can process one or more inputs by the user to generate the design prompt 260. The intent management application 170 (not shown) identifies the applicable ML models 310 and transmits the design prompt to the ML models 310. In various embodiments, the ML models 310 can generate one or more content items, including the generated 3D object 270. For example, a first ML model 310(1) can generate a 2D image based on the design prompt 260 and a second ML model 310(2) can generate the 3D object 270. In various embodiments, the generated 3D object 270 can be a mesh, a point cloud, or a boundary object that is not a parametric-based object. For example, the generated 3D object 270 can be a mesh wireframe of a door, where individual components of the door (e.g., window slots, handle, hinges, etc.) are considered the same mass and are not separate and do not have corresponding parameters. The generated 3D object 270 can then be transmitted to the design object generator 250 and the design object generator 250 can respond by automatically generating the design object 272.

In various embodiments, the design object generator 250 automatically converts the generated 3D object 270 into the generated design object 272. where the generated design object 272 is parametric-based and has a corresponding set of features. In some embodiments, the generated 3D object 270 is a mesh, wireframe, or point claim. In such instances, the boundary identifier 360 included in the design object generator 250 automatically converts the generated 3D object 270 to the generated boundary object 362. For example, the boundary identifier 360 can add faces to the point cloud or the mesh to generate a boundary representation (BREP) of the point cloud or mesh. In such instances, the generated boundary object 362 includes sets of vertices, edges, and faces representing the exterior boundaries of the point cloud or mesh.

In various embodiments, the feature extractor 370 converts the generated boundary object 362 to the generated design object 272. In some embodiments, boundary identifier 360 transmits the generated boundary object 362 to the feature extractor 370, whereupon the feature extractor 370 extracts a set of features that correspond to one or more design objects 272. In some embodiments, the feature extractor 370 recognizes combinations of geometry, such as lines and arcs and maps the geometry to physical features, such as a hole or a chamfer. In various embodiments, the feature extractor 370 can extract one or more feature types, such as chamfer, coil, round, decal, emboss, fillet, flange, hole, rib, shell, and/or thread. In such instances, the resultant design object 272 includes a set of editable features that respond to edits to a given portion of the design object 272. For example, design object 272(1) including a through hole will maintain the through hole when a user changes the thickness of the surface (rather than becoming a blind hole). In some embodiments, the design object generator 250 displays an interface for the feature extractor 370. In such instances, the user can select one or more feature types to automatically extract from the generated boundary object 362. In some embodiments, the feature extractor 370 produces a plurality of generated design objects 272 (e.g., a double-hung window that includes two sashes 272(1), 272(2) and a frame 272(3)). In such instances, each of the respective design objects 272(1)-272(3) can include a distinct set of features.

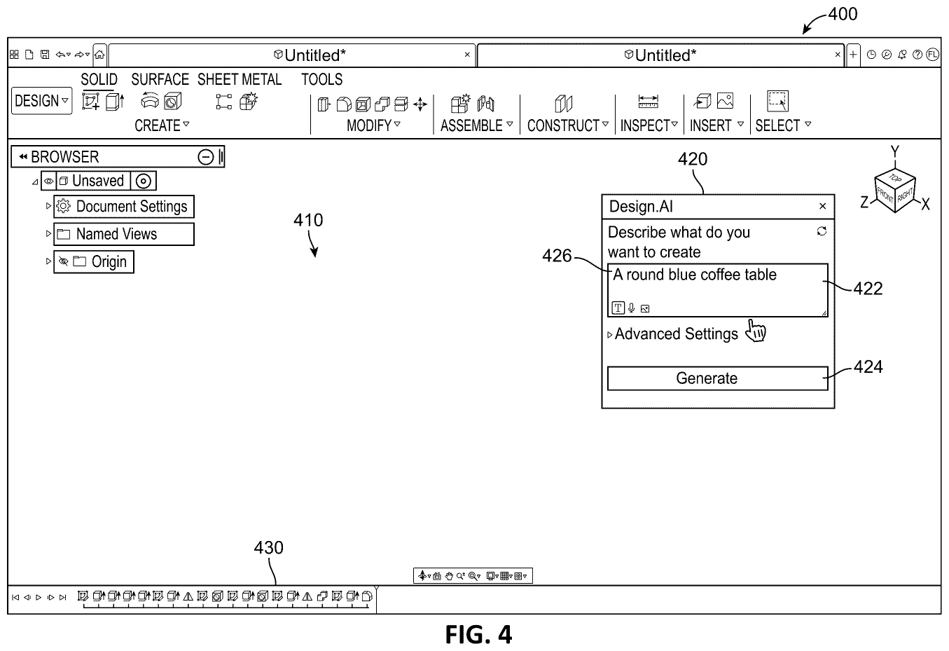

FIG. 4 is an exemplar illustration of design exploration application 130 of FIG. 2 causing the GUI 120 to display the prompt space 220, according to various embodiments. As shown, the visualization 400 includes a design space 410, a prompt input area 420, and design history 430. The prompt input area 420 includes an intent input area 422 and a trigger button 424. The intent input area 422 includes the textual phrase 426. In operation, the user invokes the prompt input area 420 to provide one or more inputs to generate a design prompt 260. The prompt input area 420 includes an intent input area 422 that enables the user to enter text, an audio recording, and/or upload one or more files. For example, the user can enter the textual phrase 426 (e.g., “a round blue coffee table”). The design history 430 illustrates a set of previous steps that the user made within the design space 410 when producing an overall 3D design.

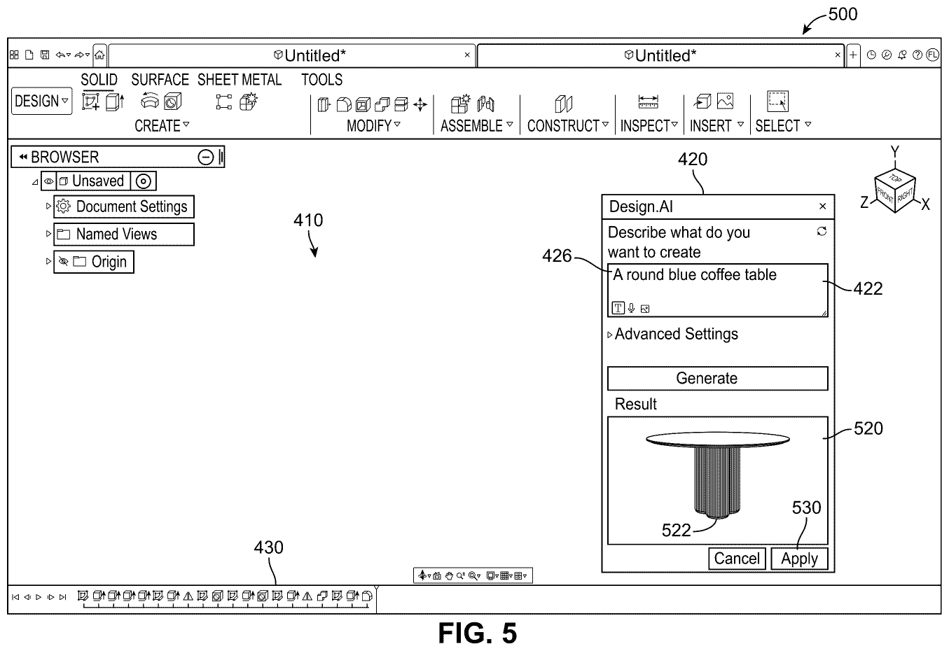

FIG. 5 is an exemplar illustration of an update to the prompt input area 420 of FIG. 4, according to various embodiments. As shown, the visualization 500 includes the design space 410, the prompt input area 420, and the design history 430. The prompt input area 420 includes the intent input area 422, a preview area 520, and a selection button 530. The intent input area 422 includes the textual phrase 426. The preview area 520 includes the generated 3D object 522. In operation, upon the user trigger button 424, the design exploration responds by generating a design prompt 260 that includes the textual phrase 426 in its contents. The design exploration application 130 transmits the design prompt 260 for the one or more ML models 310 to process. The one or more ML models 310 process the content of the design prompt 260 and generate and transmit the 3D object 522 to the design exploration application 130. In such instances, the design exploration application 130 updates the preview area 520 of the prompt input area 420 to display the generated 3D object 522. In such instances, the user can click on the select button 530 to trigger the design exploration application 130 to import the generated 3D object 522.

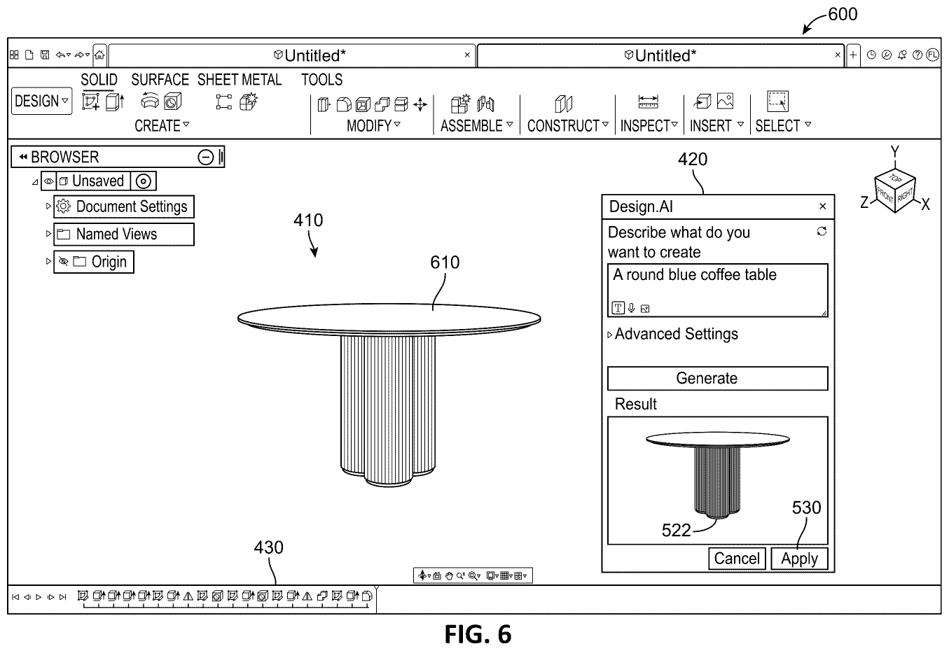

FIG. 6 is an exemplar illustration of the generated 3D object 522 of FIG. 5 being added to the design space 410, according to various embodiments. As shown, the visualization 600 includes the design space 410, the prompt input area 420, the design history 430, and a 3D object 610. The prompt input area 420 includes the intent input area 422, a preview area 520, and a selection button 530. In operation, upon the user clicking on the selection button 530, the design exploration application 130 responds by adding the generated 3D object 522 to the design space 410 as the 3D object 610. In some embodiments, the generated 3D object 522 is a mesh, point cloud, or wireframe. In such instances, the design object generator 250 uses the boundary identifier 360 to convert the generated 3D object 522 to the 3D object 610. The 3D object 610 produced by the boundary identifier 360 is a boundary representation of the generated 3D object 522 and includes one or more faces, vertices, and edges.

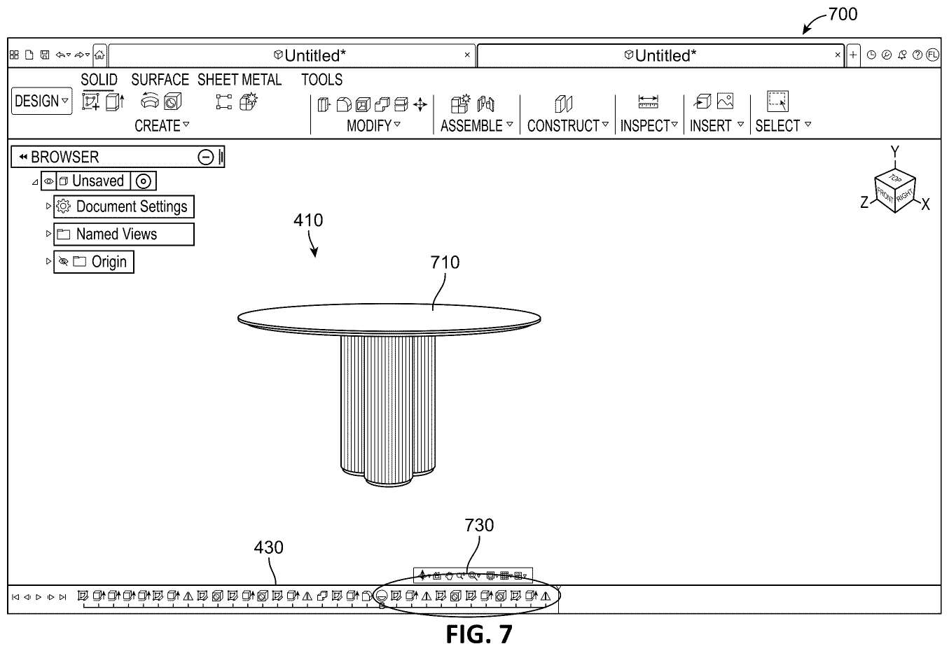

FIG. 7 is an exemplar illustration of the 3D object 610 of FIG. 6 converted to a design object including a set of features, according to various embodiments. As shown, the visualization 700 includes the design space 410, the design history 430, and a design object 710 and feature extraction history 730. In operation, the design object generator 250 uses the feature extractor 370 to convert the 3D object 610 to a design object 710. For example, upon the design exploration application 130 adding the 3D object 610 to the design space 410, the design object generator 250 can respond by performing a series of steps to extract one or more features from the 3D object 610 to generate the design object 710. As shown by the feature extraction history 730 portion of the design history 430, the feature extractor 370 can perform a series of steps (e.g., fillet, extrude, etc.) to extract a set of editable features for the design object 710. In various embodiments, the design exploration application 130 can update the GUI to display the set of features and/or display a set of parameter values corresponding to the extracted features (e.g., sliders for chamfer size, etc.).

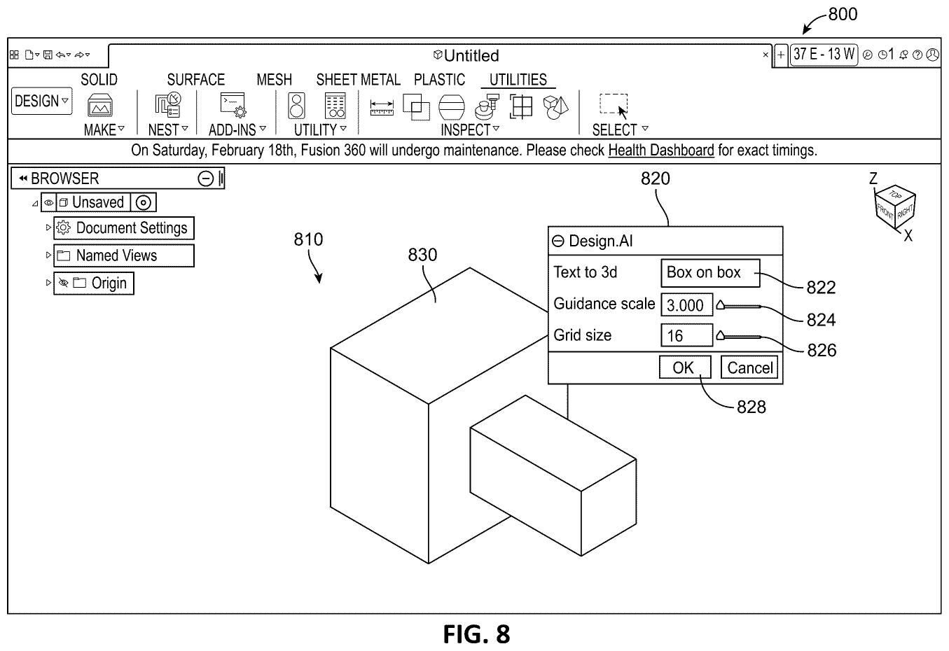

FIG. 8 is a more detailed illustration of the design exploration application of FIG. 1 producing a design prompt and converting a 3D object to a design object, according to various embodiments. As shown, the visualization 800 includes a design space 810, a prompt input area 820, and a boundary object 830. The prompt input area 820 includes an intent input area 822, a guidance scale value 824, a grid size value 826, and a trigger button 828. In operation, the design exploration application 130 can cause the GUI 120 to display a prompt input area 820 that can include various input types, including the intent input area for a user to type, as well also text input and slider combinations for users to specify values for the guidance scale and grid size. The guidance scale value 824 specifies how closely the generated 3D object is to adhere to the prompt, where higher values indicate that the generated 3D object is to adhere more closely to the contents of the prompt. The grid size value 826 indicates the size of the generated 3D object, as the grid size value 826 specifies the spacing between horizontal lines and/or vertical lines on a grid. In this manner, the user can specify a size for the generated 3D object and then incorporate the 3D object into a larger 3D design within a defined grid.

As shown, upon the user clicking on the trigger button 828, the design exploration application 130 generates a design prompt 260 that includes the text entered in the intent input area 822, as well as the guidance scale value 824 and the grid size value 826. The one or more ML models 310 respond to the design prompt 260 and generate 3D object 270. Upon the design exploration application 130 receiving the generated 3D object 270, the design object generator 250 automatically converts the generated 3D object 270 to the boundary object 830. The boundary object is a boundary representation of the generated 3D object 270 and includes a set of faces that correspond to the surface of the generated 3D object 270.

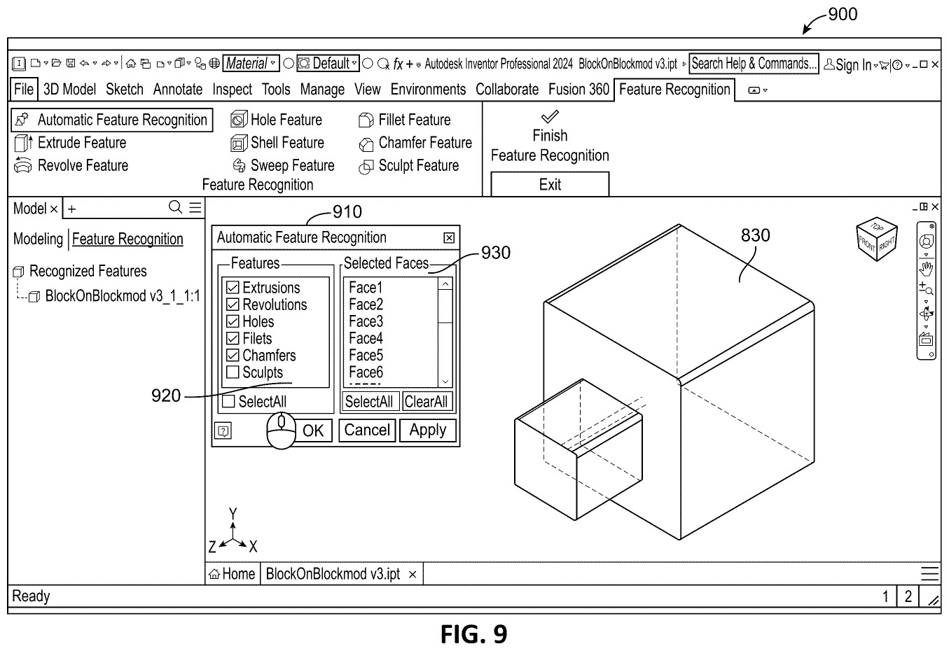

FIG. 9 is an exemplar illustration of a menu 910 for the feature extractor 370 of FIG. 3 within the design space 810, according to various embodiments. As shown, the visualization 900 includes the boundary object 830 and a feature extraction menu 910. The feature extraction menu 910 includes a list of feature types 920 and a set of faces 930. In operation, the design exploration application 130 can update the GUI 120 to display a feature recognition environment. In such instances, the design exploration application 130 can provide the feature extraction menu 910 to select specific faces of the boundary object 830 for feature extraction and one or more feature types that are to be extracted from the set of faces. For example, the user can select extrusions, revolutions, holes, fillets, chamfers, and sculpts as features to be extracted from the faces of the boundary object 830.

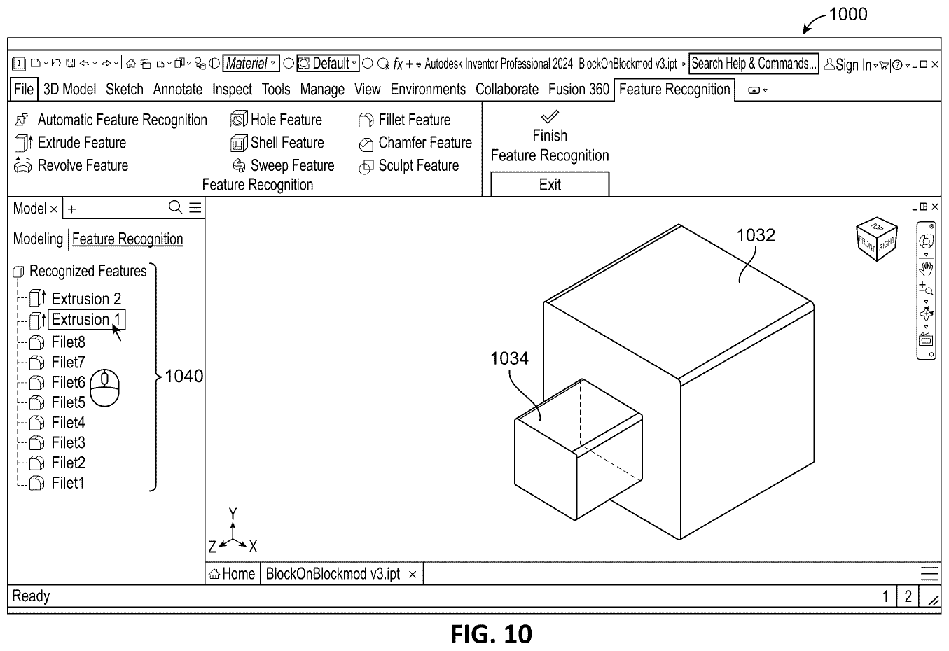

FIG. 10 is an exemplar illustration of the feature extractor 370 of FIG. 3 generating a plurality of design object 1032, 1034 and a list of editable features 1040, according to various embodiments. As shown, the visualization 1000 includes a set of design objects 1032, 1034, and a list of features 1040. In operation, the feature extractor 370 converts the boundary object 830 into a set of design objects 1032, 1034. Each of the respective design objects 1032, 1034 includes a distinct set of features. The

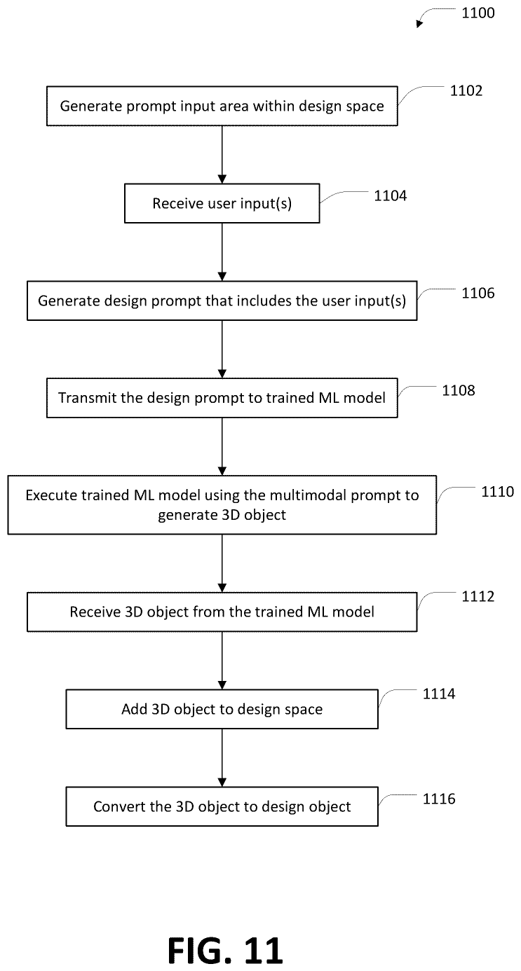

FIG. 11 sets forth a flow diagram of method steps for generating 3D objects, according to various embodiments. Although the method steps are described with reference to the systems of FIGS. 1-10 and 12, persons skilled in the art will understand that any system configured to implement the method steps, in any order, falls within the scope of the embodiments.

As shown, a method 1100 begins at step 1102, where the design exploration application 130 generates a prompt input area within a design space. In various embodiments, the design exploration application 130 overlays the prompt input area 420 as an overlay over a portion of the design space 230 in response to a user input. In such instances, the user can invoke the prompt input area 420 at various locations within the design space 230. The prompt input area 420 includes an intent input area 422 for the user to enter data. The GUI 120 displays the respective sets of features for the design objects 1032, 1034 as a single list of features 1040. In such instances, the design exploration application 130 can add the design objects 1032, 1034 to the design space 810 for incorporation into a larger 3D design. Additionally, or alternatively the design exploration application 130 can add the extracted features to the GUI 120 to enable the user to modify components of the respective design objects 1032, 1034.

At step 1104, the design exploration application 130 receives one or more user inputs. In various embodiments, the design exploration application 130 receives one or more user inputs that collectively indicate an intent for a 3D design. In various embodiments, the one or more user inputs can include textual data and/or non-textual data. For example, the user can add a textual phrase 426 within the intent input area 422 and/or select one or more design parameters, such as a guidance scale value 824 or a grid size value 826. Additionally, or alternatively in some embodiments, user can add non-textual data. For example, the user can add one or more design files 264 (e.g., a stored sketch uploaded to the intent input area 422) via the intent input area 422. As another example, the user can record a speech utterance via the intent input area 422.

At step 1106, the design exploration application 130 generates a design prompt 260 that includes the user inputs. In various embodiments, the design exploration application 130 generates a design prompt 260 that includes one or more of the user inputs added to the intent input area 422. In various embodiments, the design prompt 260 can include a single input. For example, the design prompt 260 can include design intent text 262 that the user typed via the intent input area 422. Alternatively, in some embodiments, the design prompt 260 includes two or more user inputs. For example the design prompt 260 can include multiple design intent texts, such as a typed phrase, a guidance scale value 824, and a grid size value 826. Additionally, or alternatively in some embodiments, the design prompt 260 includes two or more modalities of user input. For example, the design prompt 260 can include design intent text 262 and one or more design files 264 (e.g., a stored sketch uploaded to the intent input area 422).

At step 1108, the design exploration application 130 transmits the design prompt 260. In various embodiments, the design exploration application 130 generates the design prompt 260 and transmits the design prompt 260 to the server device 160 for input into one or more ML models 180, 190. In some embodiments, the server device 160 transmits the design prompt 260 to a single ML model (e.g., the trained ML model 180) from a plurality of ML models 310. In such instances, the intent management application 170 operating on the server device 160 can identify the contents of the design prompt 260 to identify an applicable ML model. For example, the intent management application 170 can identify the combination of modalities included in the design prompt 260 and can select an applicable ML model 180 that was trained using the identified combination of modalities.

At step 1110, the design exploration application 130 executes a trained ML model 180 using the design prompt 260 to generate a 3D object 270. In various embodiments, the design exploration application 130 causes the server device 160 to execute the at least one trained ML model 180 on the design prompt 260 to generate the 3D object 270. In various embodiments, one or more trained ML models 180 local to the server device 160 and/or one or more remote ML devices 180 are trained using multimodal prompts. The intent management application 170 inputs the design prompt 260 into the selected ML model 180.

At step 1112, the design exploration application 130 receives the generated 3D object 270 from the trained ML model 180. In various embodiments, the server device 160 receives the generated 3D object 270 from the selected ML model 180 and transmits the generated 3D object 270 to the client device 110. In such instances, the design exploration application 130 receives the generated 3D object 270 and causes the client device 110 to store the generated 3D object 270 in the local data store 140.

At step 1114, the design exploration application 130 adds the generated 3D object 270 to the design space 230. In various embodiments, the design exploration application 130, upon receiving the generated 3D object 270, adds the generated 3D object 270 to a location in the design space 230 for viewing via the GUI 120. In some embodiments, the design exploration application 130 displays the generated 3D object 270 within a preview area 520 included in the prompt space 220. In such instances, the user can review the generated 3D object 270 within the preview area 520 before providing an input to add the generated 3D object 270 to the design space 230. Alternatively, in some embodiments, the design exploration application 130 displays the generated 3D object 270 directly within the design space 230. In such instances, the design exploration application 130 can automatically convert the generated 3D object 270 to a different format. For example, the boundary identifier 360 included in the design exploration application 130 can convert the generated 3D object 270 to a generated boundary object 362.

At step 1116, the design exploration application 130 converts the 3D object to a design object. In various embodiments, the design object generator 250 included in the design exploration application 130 converts the generated 3D object 270 into the generated design object 272. In some embodiments, the boundary identifier 360 included in the design object generator 250 automatically converts the generated 3D object 270 to first a generated boundary object 362. In such instances, the feature extractor 370 included in the design object generator 250 can convert the generated boundary object 362 to the generated design object 272. The design exploration application 130 can then transmit the generated design object 272 to the GUI 120 for display within the preview area 520 included in the prompt space 220. Alternatively, in some embodiments, the design object generator 250 can automatically convert the generated 3D object 270 to a different format and can update the interface. For example, the boundary identifier 360 included in the design object generator 250 can convert the generated 3D object 270 to a generated boundary object 362. The design object generator 250 can then display an interface for the feature extractor 370 to extract one or more feature types (e.g., chamfer, hole, rib, thread, etc.) from the generated boundary object 362. In some embodiments, the feature extractor 370 produces a plurality of generated design objects 272 (e.g., the design objects 1032 and 1034). In such instances, each of the respective design objects 1032, 1034 can include a distinct set of features (e.g., the feature set 1040 for the design object 1034).

### System Implementation

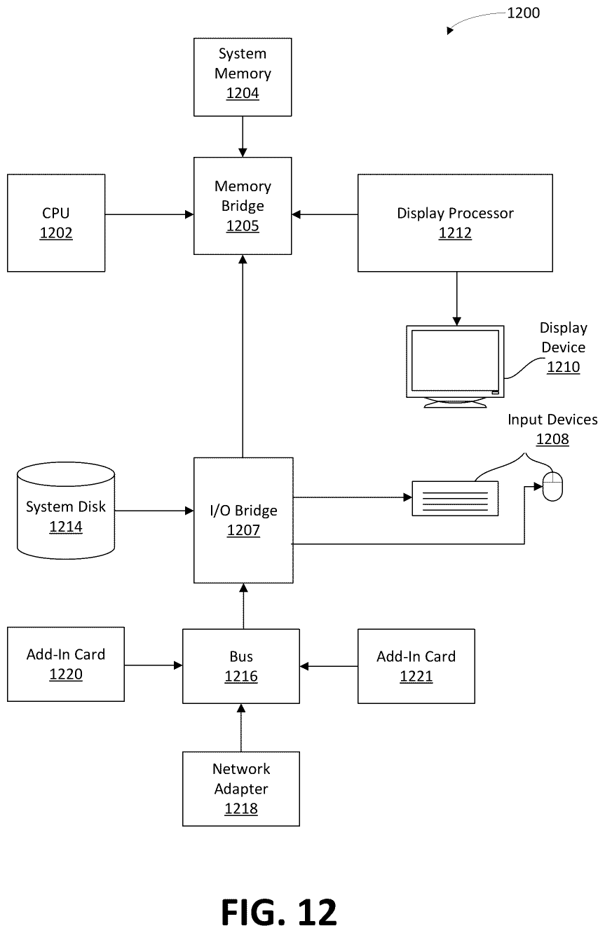

FIG. 12 depicts one architecture of a system 1200 within which embodiments of the present disclosure may be implemented. This figure in no way limits or is intended to limit the scope of the present disclosure. In various implementations, system 1200 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 1200 may be coupled together to practice one or more aspects of the present disclosure.

As shown, system 1200 includes a central processing unit (CPU) 1202 and a system memory 1204 communicating via a bus path that may include a memory bridge 1205. CPU 1202 includes one or more processing cores, and, in operation, CPU 1202 is the master processor of system 1200, controlling and coordinating operations of other system components. System memory 1204 stores software applications and data for use by CPU 1202. CPU 1202 runs software applications and optionally an operating system. Memory bridge 1205, which may be, e.g., a Northbridge chip, is connected via a bus or other communication path (e.g., a HyperTransport link) to an I/O (input/output) bridge 1207. I/O bridge 1207, which may be, e.g., a Southbridge chip, receives user input from one or more user input devices 1208 (e.g., keyboard, mouse, joystick, digitizer tablets, touch pads, touch screens, still or video cameras, motion sensors, and/or microphones) and forwards the input to CPU 1202 via memory bridge 1205.

A display processor 1212 is coupled to memory bridge 1205 via a bus or other communication path (e.g., a PCI Express, Accelerated Graphics Port, or HyperTransport link); in one embodiment display processor 1212 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 1204.

Display processor 1212 periodically delivers pixels to a display device 1210 (e.g., a screen or conventional CRT, plasma, OLED, SED or LCD based monitor or television). Additionally, display processor 1212 may output pixels to film recorders adapted to reproduce computer generated images on photographic film. Display processor 1212 can provide display device 1210 with an analog or digital signal. In various embodiments, one or more of the various graphical user interfaces set forth in Appendices A-J, attached hereto, are displayed to one or more users via display device 1210, and the one or more users can input data into and receive visual output from those various graphical user interfaces.

A system disk 1214 is also connected to I/O bridge 1207 and may be configured to store content and applications and data for use by CPU 1202 and display processor 1212. System disk 1214 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 1216 provides connections between I/O bridge 1207 and other components such as a network adapter 1218 and various add-in cards 1220 and 1221. Network adapter 1218 allows system 1200 to communicate with other systems via an electronic communications network, and may include wired or wireless communication over local area networks and wide area networks such as the Internet.

Other components (not shown), including USB or other port connections, film recording devices, and the like, may also be connected to I/O bridge 1207. For example, an audio processor may be used to generate analog or digital audio output from instructions and/or data provided by CPU 1202, system memory 1204, or system disk 1214. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 1212 incorporates circuitry optimized for graphics and video processing, including, for example, video output circuitry, and constitutes a graphics processing unit (GPU). In another embodiment, display processor 1212 incorporates circuitry optimized for general purpose processing. In yet another embodiment, display processor 1212 may be integrated with one or more other system elements, such as the memory bridge 1205, CPU 1202, and I/O bridge 1207 to form a system on chip (SoC). In still further embodiments, display processor 1212 is omitted and software executed by CPU 1202 performs the functions of display processor 1212.

Pixel data can be provided to display processor 1212 directly from CPU 1202. In some embodiments of the present disclosure, instructions and/or data representing a scene are provided to a render farm or a set of server computers, each similar to system 1200, via network adapter 1218 or system disk 1214. The render farm generates one or more rendered images of the scene using the provided instructions and/or data. These rendered images may be stored on computer-readable media in a digital format and optionally returned to system 1200 for display. Similarly, stereo image pairs processed by display processor 1212 may be output to other systems for display, stored in system disk 1214, or stored on computer-readable media in a digital format.

Alternatively, CPU 1202 provides display processor 1212 with data and/or instructions defining the desired output images, from which display processor 1212 generates the pixel data of one or more output images, including characterizing and/or adjusting the offset between stereo image pairs. The data and/or instructions defining the desired output images can be stored in system memory 1204 or graphics memory within display processor 1212. In an embodiment, display processor 1212 includes 3D rendering capabilities for generating pixel data for output images from instructions and data defining the geometry, lighting shading, texturing, motion, and/or camera parameters for a scene. Display processor 1212 can further include one or more programmable execution units capable of executing shader programs, tone mapping programs, and the like.

Further, in other embodiments, CPU 1202 or display processor 1212 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 1202, display processor 1212, or one or more other processing devices or any combination of these different processors.

CPU 1202, render farm, and/or display processor 1212 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 1200 may be a robot or robotic device and may include CPU 1202 and/or other processing units or devices and system memory 1204. In such embodiments, system 1200 may or may not include other elements shown in FIG. 1. System memory 1204 and/or other memory units or devices in system 1200 may include instructions that, when executed, cause the robot or robotic device represented by system 1200 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 1204 is connected to CPU 1202 directly rather than through a bridge, and other devices communicate with system memory 1204 via memory bridge 1205 and CPU 1202. In other alternative topologies display processor 1212 is connected to I/O bridge 1207 or directly to CPU 1202, rather than to memory bridge 1205. In still other embodiments, I/O bridge 1207 and memory bridge 1205 might be integrated into a single chip. The particular components shown herein are optional; for instance, any number of add-in cards or peripheral devices might be supported. In some embodiments, switch 1216 is eliminated, and network adapter 1218 and add-in cards 1220, 1221 connect directly to I/O bridge 1207.

In sum, the disclosed techniques can be used to generate designs for one or more 3D objects based on design intentions expressed by users using one or more modalities provided via a GUI. In various embodiments, a design exploration application displays a prompt input area for a user to generate a design prompt. The prompt input enables the user to specify the design intent via a textual input and/or one or more non-textual inputs, which can include sketches, stored files (e.g., stored images, previous designs, stored sketches, and so forth), and/or audio inputs. The design exploration application then generates a design that includes the intent inputs. The design exploration application transmits the design prompt to an intent management application operating at a server device. Upon receipt, the intent management application identifies one or more generative ML models that are trained to process the content included in the design prompt. The intent management application inputs the design prompt to the identified generative ML model. The generative ML model can be local or remote to the server device. The generative ML model, which was trained using design histories of design prompts, generated content items, and evaluations of the generated content items, generates a content item, such as a 3D design, that is responsive to the design prompt. The design exploration application receives the one or more generated design objects from the server device and displays the 3D design via the GUI. In response to the user selecting the 3D design for use, the design exploration application adds the 3D design to the design space. In some embodiments, the design exploration application automatically converts the 3D design into a design object that includes a set of editable features. Alternatively, the design exploration application responds to one or more user inputs by extracting one or more types of features from the 3D design to generate the design object.

At least one technical advantage of the disclosed techniques relative to the prior art is that the disclosed techniques enable design systems to incorporate generative artificial intelligence systems that determine the design intent of a user more accurately. Further, design systems using the disclosed techniques can automatically convert content items produced by such generative artificial intelligence system to parametric-based design objects that include a set of editable features. In that regard, the disclosed techniques provide an automated process for generating prompts from inputs provided by the user, including combinations of text, speech, sketches, images, and/or stored designs. Generating prompts using varying types of data enables a user to provide additional context to portions of a prompt that a trained generative artificial intelligence model can understand, which enables the generative artificial intelligence model to better infer the design intents and ideas of the user. Further, by automatically converting content items into parametric-based 3D design objects that can be easily added to the design space, the design system can quickly incorporate outputs of the generative artificial intelligence system into overall 3D designs to generate large numbers of alternative designs. Accordingly, with the disclosed techniques, 3D design objects that align better with the actual design-oriented intentions and ideas of users can be more readily generated and manufactured. These technical advantages provide one or more technological advancements over prior art approaches.
1. In various embodiments, a computer-implemented method for generating a design object via a design exploration application comprises receiving an intent input, where the intent input includes at least a textual input, generating, based on the intent input, a design prompt, generating, via a trained machine learning (ML) model, a three-dimensional object based on the design prompt, converting the three-dimensional object to the design object, where the design object includes one or more editable features, and adding the design object to a design space.
2. The computer-implemented method of clause 1, further comprising receiving at least one of a text string, a grid size, or a guidance scale as input via a graphical user interface, where the textual input includes the text string, the grid size, or the guidance scale.
3. The computer-implemented method of clause 1 or 2, further comprising transmitting the design prompt to a remote device for processing by the ML model to generate the three-dimensional object.
4. The computer-implemented method of any of clauses 1-3, where the three-dimensional object comprises at least one of a mesh representation or a point cloud.
5. The computer-implemented method of any of clauses 1-4, further comprising converting the three-dimensional object to a boundary object, where the design object is based on the boundary object.
6. The computer-implemented method of any of clauses 1-4, further comprising extracting one or more features from the boundary object to generate the design object, where the design object includes the one or more editable features.
7. The computer-implemented method of any of clauses 1-6, further comprising extracting one or more features from the boundary object to generate a plurality of design objects, where the plurality of design objects includes at least the design object and a second design object.
8. The computer-implemented method of any of clauses 1-7, where the intent input further includes a non-textual input comprising at least one of a CAD file, an image, a sketch, or an audio recording.
9. The computer-implemented method of any of clauses 1-8, further comprising generating a prompt input area within the design space, where the prompt input area includes an intent input area through which the intent input is received.
10. The computer-implemented method of any of clauses 1-9, where the prompt input area further includes a preview area that displays the three-dimensional object.
11. In various embodiments, one or more non-transitory computer-readable media includes instructions that, when executed by one or more processors, cause the one or more processors to generate a design object via a design exploration application by performing the steps of receiving an intent input, where the intent input includes at least a textual input, generating, based on the intent input, a design prompt, generating, via a trained machine learning (ML) model, a three-dimensional object based on the design prompt, converting the three-dimensional object to the design object, where the design object includes one or more editable features, and adding the design object to a design space.
12. The one or more non-transitory computer-readable media of clause 11, where the one or more editable features comprises at least one of a chamfer, a coil, a round, a decal, an emboss, a fillet, a flange, a hole, a rib, a shell, or a thread.
13. The one or more non-transitory computer-readable media of clause 11 or 12, further comprising instructions that, when executed by the one or more processors, cause the one or more processors to perform the steps of adding the three-dimensional object to the design space, and detecting a user input associated with the three-dimensional object in the design space, where three-dimensional object is converted to the design object in response to the user input.
14. The one or more non-transitory computer-readable media of any of clauses 11-13, further comprising instructions that, when executed by the one or more processors, cause the one or more processors to perform the steps of generating a set of parameters based on the one or more editable features, and displaying the set of parameters via a graphical user interface.
15. The one or more non-transitory computer-readable media of any of clauses 11-14, where the three-dimensional object comprises at least one of a mesh representation or a point cloud.
16. The one or more non-transitory computer-readable media of any of clauses 11-15, further comprising instructions that, when executed by the one or more processors, cause the one or more processors to perform the step of converting the three-dimensional object to a boundary object, where the design object is based on the boundary object.
17. The one or more non-transitory computer-readable media of any of clauses 11-16, further comprising instructions that, when executed by the one or more processors, cause the one or more processors to perform the step of extracting one or more features from the boundary object to generate the design object, where the design object includes the one or more editable features.
18. The one or more non-transitory computer-readable media of any of clauses 11-17, further comprising instructions that, when executed by the one or more processors, cause the one or more processors to perform the step of extracting one or more features from the boundary object to generate a plurality of design objects, where the plurality of design objects includes at least the design object and a second design object.
19. The one or more non-transitory computer-readable media of any of clauses 11-18, where the intent input further includes a non-textual input comprising at least one of a CAD file, an image, a sketch, or an audio recording.
20. In various embodiments, a system comprises one or more memories storing instructions, and one or more processors coupled to the one or more memories that, when executing the instructions, generate a design object via a design exploration application by performing the steps of receiving, by a design exploration application, an intent input, where the intent input includes at least a textual input, generating, based on the intent input, a design prompt, executing a trained machine learning (ML) model on the design prompt to generate a three-dimensional object, converting, by the design exploration application, the three-dimensional object to a design object, where the design object includes one or more editable features, and adding the design object to a design space.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating a design object via a design exploration application, the computer-implemented method comprising:
receiving an intent input, wherein the intent input includes at least a textual input;
generating, based on the intent input, a design prompt;
generating, via a trained machine learning (ML) model, a three-dimensional object based on the design prompt;
converting the three-dimensional object to the design object, wherein the design object includes one or more editable features; and
adding the design object to a design space.

2. The computer-implemented method of claim 1, further comprising receiving at least one of a text string, a grid size, or a guidance scale as input via a graphical user interface, wherein the textual input includes the text string, the grid size, or the guidance scale.

3. The computer-implemented method of claim 2, further comprising transmitting the design prompt to a remote device for processing by the ML model to generate the three-dimensional object.

4. The computer-implemented method of claim 1, wherein the three-dimensional object comprises at least one of a mesh representation or a point cloud.

5. The computer-implemented method of claim 1, further comprising converting the three-dimensional object to a boundary object, wherein the design object is based on the boundary object.

6. The computer-implemented method of claim 5, further comprising extracting one or more features from the boundary object to generate the design object, wherein the design object includes the one or more editable features.

7. The computer-implemented method of claim 5, further comprising extracting one or more features from the boundary object to generate a plurality of design objects, wherein the plurality of design objects includes at least the design object and a second design object.

8. The computer-implemented method of claim 1, wherein the intent input further includes a non-textual input comprising at least one of a CAD file, an image, a sketch, or an audio recording.

9. The computer-implemented method of claim 1, further comprising generating a prompt input area within the design space, wherein the prompt input area includes an intent input area through which the intent input is received.

10. The computer-implemented method of claim 9, wherein the prompt input area further includes a preview area that displays the three-dimensional object.

11. One or more non-transitory computer-readable media including instructions that, when executed by one or more processors, cause the one or more processors to generate a design object via a design exploration application by performing the steps of:
receiving an intent input, wherein the intent input includes at least a textual input;
generating, based on the intent input, a design prompt;
generating, via a trained machine learning (ML) model, a three-dimensional object based on the design prompt;
converting the three-dimensional object to the design object, wherein the design object includes one or more editable features; and
adding the design object to a design space.

12. The one or more non-transitory computer-readable media of claim 11, wherein the one or more editable features comprises at least one of a chamfer, a coil, a round, a decal, an emboss, a fillet, a flange, a hole, a rib, a shell, or a thread.

13. The one or more non-transitory computer-readable media of claim 11, further comprising instructions that, when executed by the one or more processors, cause the one or more processors to perform the steps of:
adding the three-dimensional object to the design space; and
detecting a user input associated with the three-dimensional object in the design space, wherein three-dimensional object is converted to the design object in response to the user input.

14. The one or more non-transitory computer-readable media of claim 11, further comprising instructions that, when executed by the one or more processors, cause the one or more processors to perform the steps of:
generating a set of parameters based on the one or more editable features; and
displaying the set of parameters via a graphical user interface.

15. The one or more non-transitory computer-readable media of claim 11, wherein the three-dimensional object comprises at least one of a mesh representation or a point cloud.

16. The one or more non-transitory computer-readable media of claim 11, further comprising instructions that, when executed by the one or more processors, cause the one or more processors to perform the step of converting the three-dimensional object to a boundary object, wherein the design object is based on the boundary object.

17. The one or more non-transitory computer-readable media of claim 16, further comprising instructions that, when executed by the one or more processors, cause the one or more processors to perform the step of extracting one or more features from the boundary object to generate the design object, wherein the design object includes the one or more editable features.

18. The one or more non-transitory computer-readable media of claim 16, further comprising instructions that, when executed by the one or more processors, cause the one or more processors to perform the step of extracting one or more features from the boundary object to generate a plurality of design objects, wherein the plurality of design objects includes at least the design object and a second design object.

19. The one or more non-transitory computer-readable media of claim 11, wherein the intent input further includes a non-textual input comprising at least one of a CAD file, an image, a sketch, or an audio recording.

20. A system comprising:
one or more memories storing instructions; and
one or more processors coupled to the one or more memories that, when executing the instructions, generate a design object via a design exploration application by performing the steps of:
receiving, by a design exploration application, an intent input, wherein the intent input includes at least a textual input;
generating, based on the intent input, a design prompt;
executing a trained machine learning (ML) model on the design prompt to generate a three-dimensional object;
converting, by the design exploration application, the three-dimensional object to a design object, wherein the design object includes one or more editable features; and
adding the design object to a design space.
